(19) United States
(12) Patent Application Publication
(10) Pub. No.: US 2024/0282692 A1
(43) Pub. Date: Aug. 22, 2024

(54) SEMICONDUCTOR DEVICE

(71) Applicant: Rohm Co., Ltd., Kyoto-shi (JP)

(72) Inventor: Yo MOCHIZUKI, Kyoto-shi (JP)

(21) Appl. No.: 18/652,365

(22) Filed: May 1, 2024

Related U.S. Application Data
(63) Continuation of application No. PCT/JP2022/045063, filed on Dec. 7, 2022.

(30) Foreign Application Priority Data
Dec. 24, 2021 (JP) 2021-210252

(51) Int. Cl. H01L 23/498; H01L 23/00; H01L 23/367; H01L 23/373; H01L 25/07

(52) U.S. Cl. CPC H01L 23/49844; H01L 23/367; H01L 23/3735; H01L 23/49822; H01L 24/06; H01L 25/072; H01L 23/49811; H01L 24/29; H01L 24/32; H01L 24/37; H01L 24/40; H01L 24/45; H01L 24/48; H01L 24/49; H01L 24/73; H01L 2224/0603; H01L 2224/06181; H01L 2224/29139; H01L 2224/32225; H01L 2224/37147; H01L 2224/40137; H01L 2224/40225; H01L 2224/40499; H01L 2224/45124; H01L 2224/45144; H01L 2224/45147; H01L 2224/48091; H01L 2224/48225; H01L 2224/49175; H01L 2224/73221; H01L 2224/73263; H01L 2224/73265; H01L 2924/01047; H01L 2924/10272; H01L 2924/13055; H01L 2924/13091

(57) ABSTRACT

A semiconductor device includes a conductive member, a semiconductor element, and a sealing resin. The conductive member includes an obverse surface and a reverse surface facing away from each other in a thickness direction. The semiconductor element is bonded to the obverse surface. The sealing resin covers the conductive member and the semiconductor element. As viewed in the thickness direction, the obverse surface is surrounded by the reverse surface. The conductive member includes a first end surface located between the obverse surface and the reverse surface in the thickness direction. The first end surface is inclined relative to the reverse surface. The first end surface overlaps with the reverse surface as viewed in the thickness direction.

### TECHNICAL FIELD

The present disclosure relates to semiconductor devices.

### BACKGROUND ART

Semiconductor devices incorporating semiconductor elements having a switching function are conventionally known. Such semiconductor devices are mainly used for power conversion. JP-A-2013-258387 discloses an example of such a semiconductor device.

The semiconductor device disclosed in JP-A-2013-258387 includes a semiconductor element electrically bonded to a copper plate layer. The semiconductor element and the copper plate layer are covered with a resin layer. For good adhesion of the resin layer to the copper plate layer, primer may be applied to the copper plate layer before the process of forming the resin layer. Although a thicker copper plate layer can more efficiently dissipate heat from the semiconductor element to the outside, primer applied to the thick copper plate layer tends to flow out during the process of forming the resin layer. Flowing of the primer can result in the void formation at the interface between the copper plate and the resin layer. The void formation to a greater extent can decrease the dielectric strength of the semiconductor device.

### BRIEF DESCRIPTION OF THE DRAWINGS

FIG. 1 is a perspective view of a semiconductor device according to a first embodiment of the present disclosure, omitting a sealing resin.

FIG. 2 is a plan view of the semiconductor device shown in FIG. 1, with the sealing resin shown as transparent.

FIG. 3 is a plan view corresponding to FIG. 2, with a second terminal shown as transparent.

FIG. 4 is a bottom view of the semiconductor device shown in FIG. 1.

FIG. 5 is a left-side view of the semiconductor device shown in FIG. 1.

FIG. 6 is a sectional view taken along line VI-VI in FIG. 2.

FIG. 7 is a sectional view taken along line VII-VII in FIG. 2.

FIG. 8 is a sectional view taken along line VIII-VIII in FIG. 2.

FIG. 9 is a sectional view taken along line IX-IX in FIG. 2.

FIG. 10 is a partially enlarged view of FIG. 6, showing a portion around a first semiconductor element.

FIG. 11 is a partially enlarged view of FIG. 6, showing a portion around a second semiconductor element.

FIG. 12 is a partially enlarged view of FIG. 3.

FIG. 13 is a partially enlarged view of FIG. 7.

FIG. 14 is a partially enlarged sectional view of a semiconductor device according to a variation of the first embodiment of the present disclosure.

FIG. 15 is a sectional view of a semiconductor device according to a second embodiment of the present disclosure.

FIG. 16 is a sectional view of the semiconductor device shown in FIG. 15, showing a portion around a first member.

FIG. 17 is a sectional view of the semiconductor device shown in FIG. 15, showing a portion around a second member.

FIG. 18 is a partially enlarged view of FIG. 15.

FIG. 19 is a sectional view of a semiconductor device according to a third embodiment of the present disclosure.

FIG. 20 is a partially enlarged view of FIG. 19.

### DETAILED DESCRIPTION OF EMBODIMENTS

The following describes embodiments for carrying out the present disclosure, with reference to the accompanying drawings.

### First Embodiment

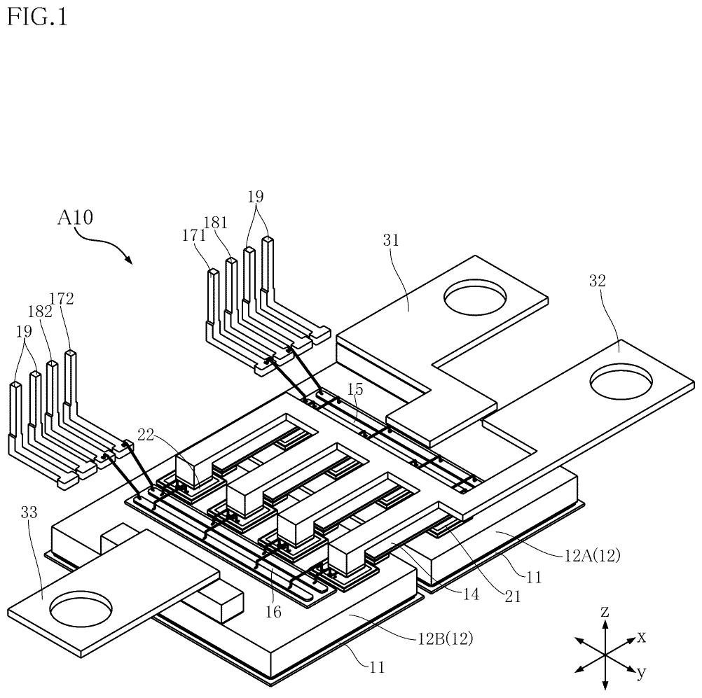

With reference to FIGS. 1 to 13, the following describes a semiconductor device A10 according to a first embodiment of the present disclosure. The semiconductor device A10 includes two insulating members 11, two conductive members 12, two heat dissipating members 13, a plurality of conducting members 14, a plurality of first semiconductor elements 21, a plurality of second semiconductor elements 22, and a sealing resin 50.

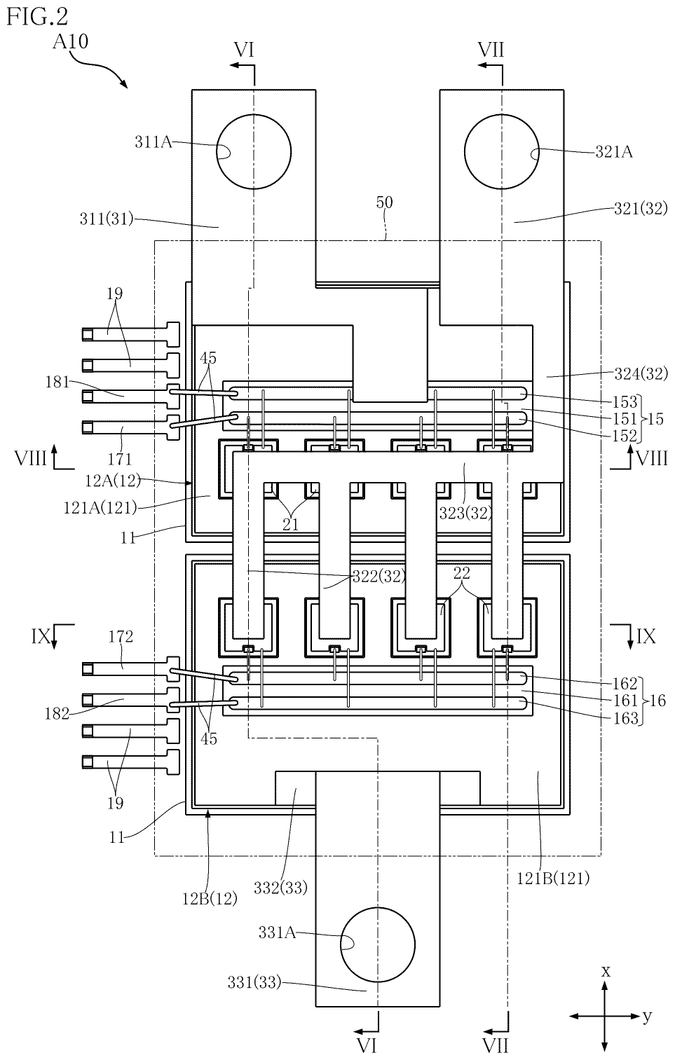

The semiconductor device A10 additionally includes a first wiring 15, a second wiring 16, a first gate terminal 171, a second gate terminal 172, a first sensing terminal 181, a second sensing terminal 182, a plurality of first wires 41, a plurality of second wires 42, a plurality of third wires 43, a plurality of fourth wires 44, and a plurality of fifth wires 45. For convenience, FIG. 1 omits the sealing resin 50. For convenience, FIG. 2 shows the sealing resin 50 as transparent, with the outline of the sealing resin 50 indicated by imaginary lines (two-dot-dash lines). FIG. 2 also shows the lines VI-VI and VII-VII by dot-dash lines.

For convenience in describing the semiconductor device A10, the direction of the normal to the obverse surfaces 121 of the two conductive members 12 described below is referred to as the “thickness direction z”. A direction orthogonal to the thickness direction z is referred to as the “first direction x”. The direction orthogonal to the thickness direction z and the first direction x is referred to as the “second direction y”.

The semiconductor device A10 converts a DC source voltage applied to the first terminal 31 and the second terminal 32 into AC power by the first semiconductor elements 21 and the second semiconductor elements 22. The resulting AC power is fed from the third terminal 33 to a power supply destination, such as a motor. The semiconductor device A10 can form part of a power converting circuit, such as an inverter.

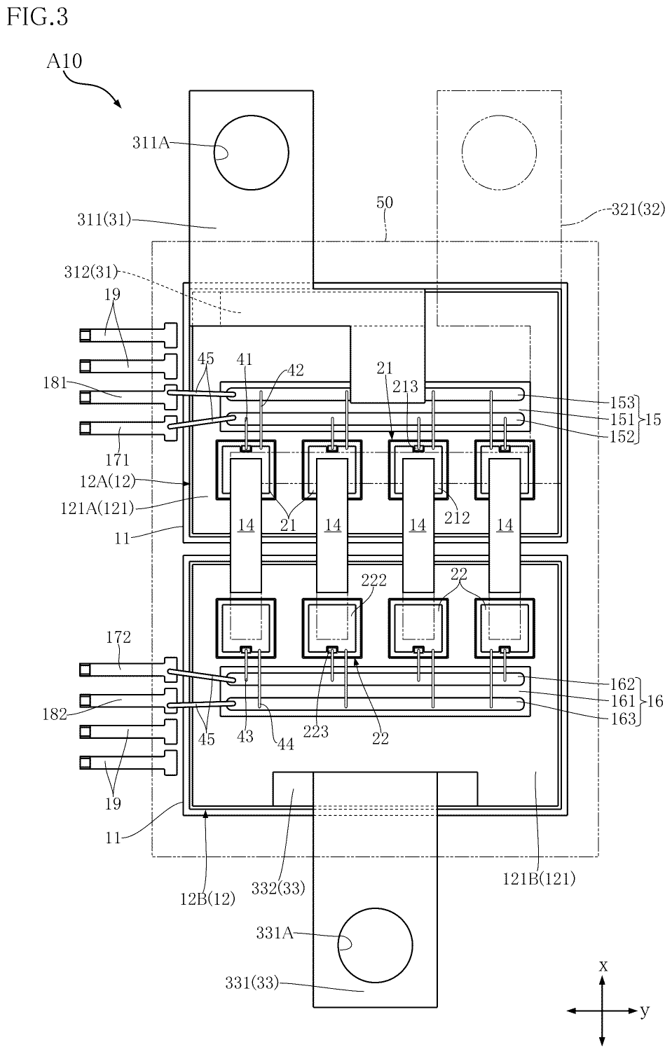

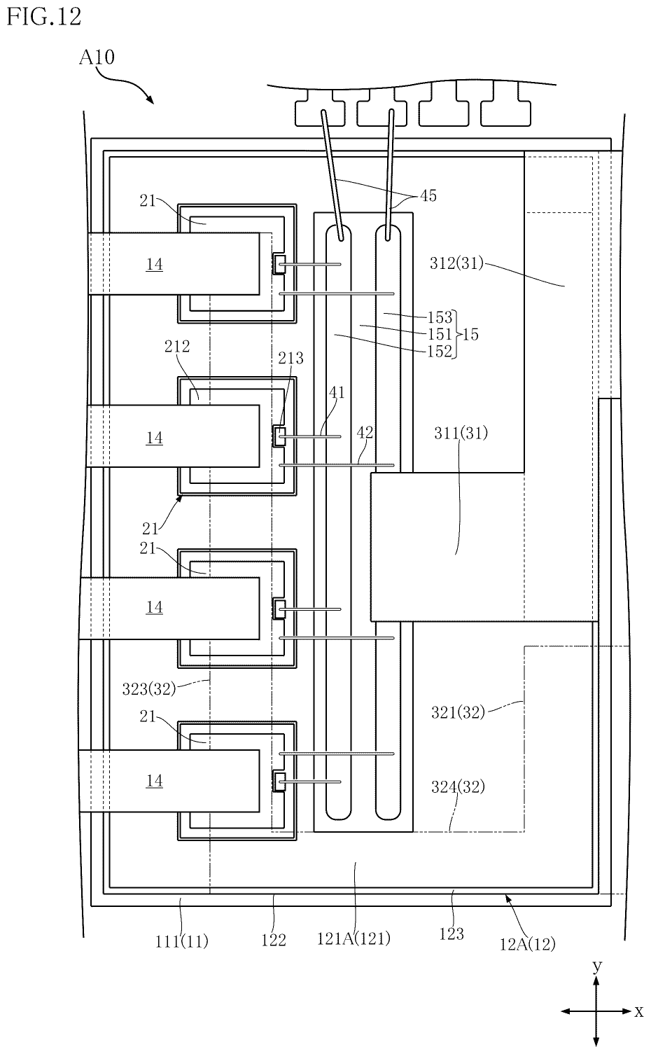

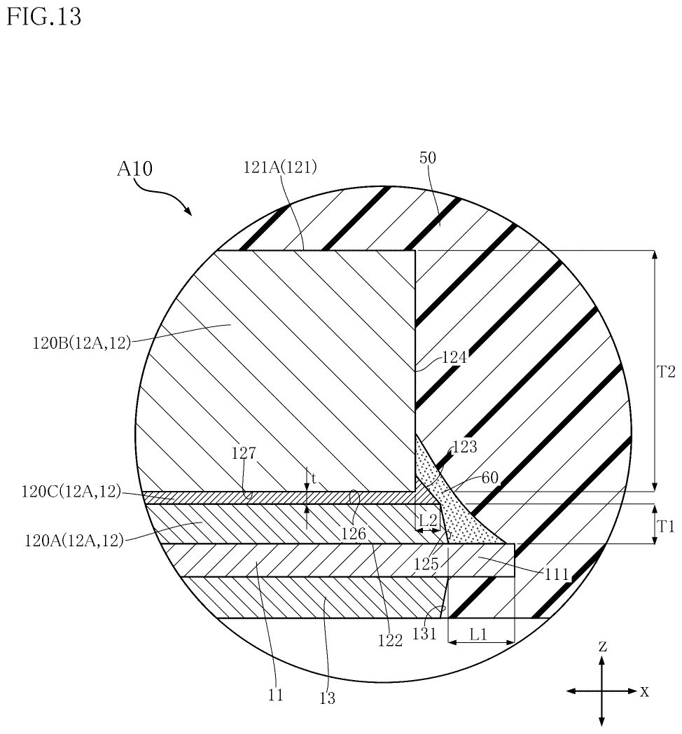

As shown in FIGS. 2 and 3, the two insulating members 11 are spaced apart from each other in the first direction x. The two insulating members 11 are made of a resin material In another example, the two containing an epoxy resin. insulating members 11 may be made of a ceramic material containing aluminum nitride (AlN). As shown in FIGS. 12 and 13, each of the two insulating members 11 has a peripheral portion 111. The peripheral portion 111 extends outward from the conductive member 12 as viewed in the thickness direction z. In the thickness direction z, the peripheral portion 111 is sandwiched by the sealing resin 50.

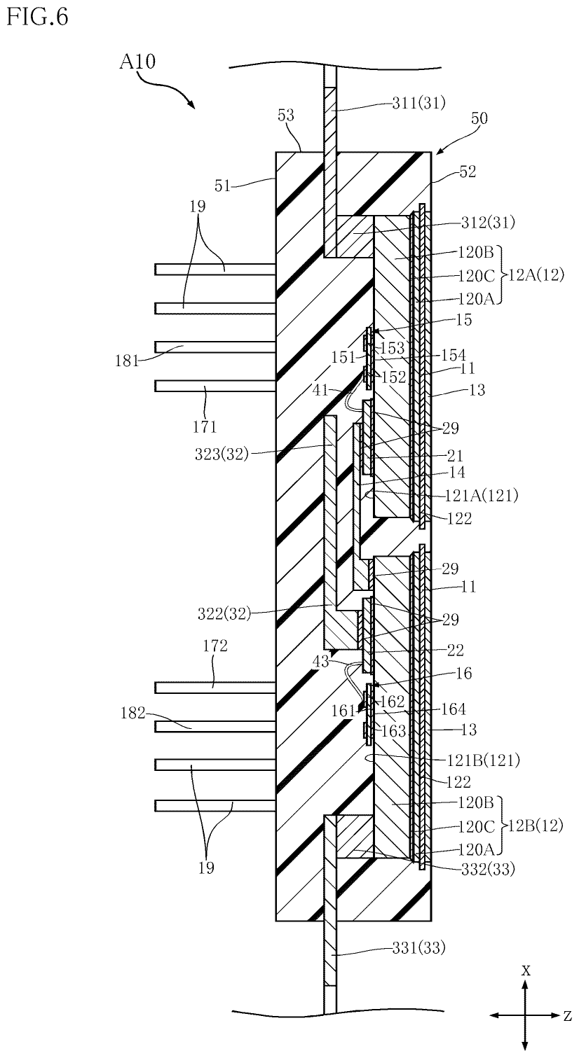

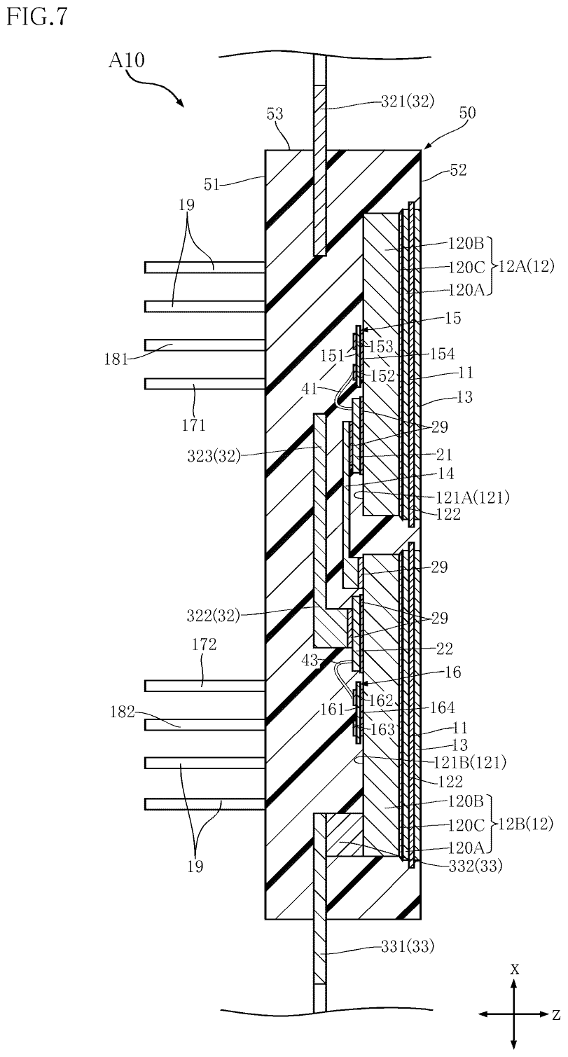

In the thickness direction z, the two conductive members 12 are located between where the two insulating members 11 are located and where the first semiconductor elements 21 and the second semiconductor elements 22 are located as shown in FIGS. 6 and 7. The two conductive members 12 are bonded to the two insulating members 11 individually. In the description of the semiconductor device A10, the conductive member 12 on which the first semiconductor elements 21 are mounted is referred to as a “first member 12A”, and the conductive member 12 on which the second semiconductor elements 22 are mounted is referred to as a “second member 12B”.

Each of the two conductive members 12 includes an obverse surface 121, a reverse surface 122, and a first end surface 123. The obverse surface 121 and the reverse surface 122 face away from each other in the thickness direction z. The obverse surface 121 includes a first obverse surface 121A of the first member 12A and a second obverse surface 121B of the second member 12B. The first obverse surface 121A faces the first semiconductor elements 21. The second obverse surface 121B faces the second semiconductor elements 22. The reverse surface 122 is bonded to the two insulating members 11. As shown in FIG. 12, the obverse surface 121 is surrounded by the peripheral edge of the reverse surface 122 as viewed in the thickness direction z. That is, the obverse surface 121 is smaller in area than the reverse surface 122.

As shown in FIG. 13, the first end surface 123 is located between the obverse surface 121 and the reverse surface 122 in the thickness direction z. The first end surface 123 is inclined relative to the reverse surface 122. As viewed in thickness direction z, the first end surface 123 overlaps with the reverse surface 122.

As shown in FIGS. 6 to 9, for the semiconductor device A10, each of the two conductive members 12 includes a first layer 120A, a second layer 120B, and a bonding layer 120C. As shown in FIG. 13, the first layer 120A includes the reverse surface 122, and the second layer 120B includes the obverse surface 121. The compositions of the first layer 120A and the second layer 120B includes copper (Cu) . In the thickness direction z, the first layer 120A has a dimension T1 and the second layer 120B has a dimension T2, where the dimension T2 is greater than the dimension T1. The bonding layer 120C includes the first end surface 123. The bonding layer 120C electrically bonds the first layer 120A and the second layer 120B. The bonding layer 120C contains a metallic element. The metallic element may be tin (Sn), for example.

As shown in FIG. 13, the second layer 120B includes a second end surface 124 connected to the obverse surface 121. The second end surface 124 faces in a direction orthogonal to the thickness direction z. The bonding layer 120C is in contact with the second end surface 124.

As shown in FIG. 13, the first layer 120A includes a third end surface 125 connected to the reverse surface 122. The third end surface 125 is inclined relative to the reverse surface 122. As viewed in thickness direction z, the third end surface 125 overlaps with the reverse surface 122.

As shown in FIG. 13, the first layer 120A includes a first bonding surface 126 facing the bonding layer 120C and connected to the third end surface 125. The bonding layer 120C is in contact with the first bonding surface 126 and the boundary between the third end surface 125 and the first bonding surface 126.

As shown in FIG. 13, the second layer 120B includes a second bonding surface 127 facing the bonding layer 120C and connected to the second end surface 124. The bonding layer 120C is in contact with the second bonding surface 127. In the thickness direction z, the distance t between the first layer 120A and the second layer 120B is smaller than the dimension T1 of the first layer 120A. The distance t is equal to a dimension of the bonding layer 120C in the thickness direction located between the first bonding surface 126 and the second bonding surface 127.

As shown in FIG. 13, the semiconductor device A10 additionally includes a primer 60 for improving the adhesion of the sealing resin 50 to the two conductive members 12. The primer 60 is electrically insulating. The primer 60 may contain polyimide, for example. The primer 60 is in contact with the peripheral portion 111 of each of the two insulating members 11 and the first end surface 123, the second end surface 124, and the third end surface 125 of each of the two conductive members 12. In the first direction x, the peripheral portion 111 has a dimension L1 and the first end surface 123 has a dimension L2, where the dimension L1 is greater than the dimension L2. In the thickness direction, the dimension of the insulating members 11 is smaller than the dimension T1 of the first layers 120A of the two conductive members 12.

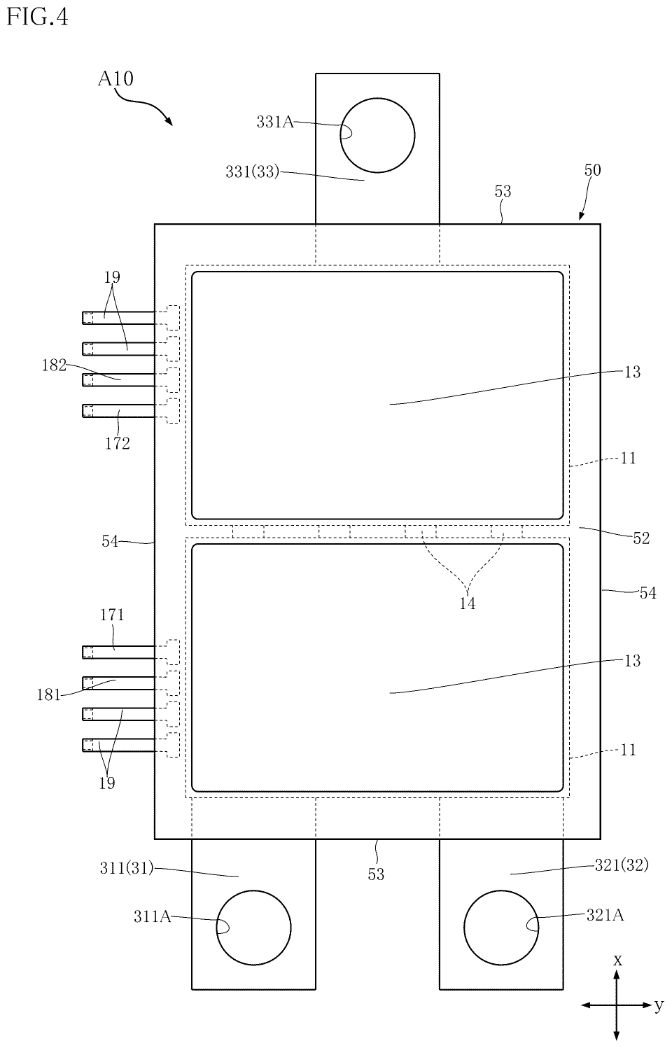

As shown in FIGS. 6 and 7, in the thickness direction z, the two heat dissipating members 13 are disposed on the side opposite to the two conductive members 12 with respect to the two insulating members 11. The two heat dissipating members 13 are bonded to the two insulating members 11 individually. The two heat dissipating members 13 include copper in their composition. Each of the two heat dissipating members 13 includes an end surface 131 facing in a direction orthogonal to the thickness direction z. As viewed in the thickness direction z, the end surface 131 is surrounded by the peripheral edge of the insulating member 11. As shown in FIG. 4, each of the two heat dissipating members 13 has a portion exposed to the outside from the sealing resin 50. When the semiconductor device A10 is put to use, a heat sink (not shown) is bonded to the two heat dissipating members 13.

The two insulating members 11, the first layers 120A of the two conductive members 12, and the two heat dissipating members 13 can be easily fabricated from a direct bonded copper (DBC) substrate. The third end surfaces 125 of the first layers 120A and the end surfaces 131 of the heat dissipating members 13 are formed by etching.

As shown in FIGS. 6 to 8, the first semiconductor elements 21 are bonded to the first obverse surface 121A of the first member 12A. The first semiconductor elements 21 are identical to each other. In one example, the first semiconductor elements 21 are metal-oxide-semiconductor field-effect transistors (MOSFETs). In other examples, the first semiconductor elements 21 may be field-effect transistors, including metal-insulator-semiconductor field-effect transistors (MISFETs), or bipolar transistors, such as insulated transistors In the gate bipolar (IGBTs). description of the semiconductor device A10, the first semiconductor elements 21 are n-channel, vertical MOSFETs. The first semiconductor elements 21 include a compound semiconductor substrate. The compound semiconductor substrate includes silicon carbide (SiC) in its composition. The first semiconductor elements 21 are aligned in the second direction y.

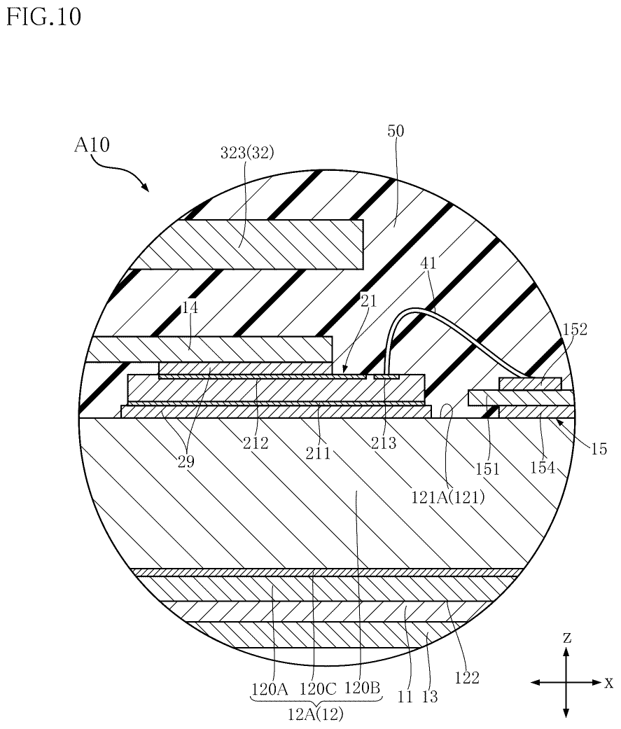

As shown in FIG. 10, each first semiconductor element 21 includes a first reverse-surface electrode 211, a first obverse-surface electrode 212, and a first gate electrode 213.

As shown in FIG. 10, the first reverse-surface electrode 211 faces the first obverse surface 121A of the first member 12A. The first reverse-surface electrode 211 will carry the current corresponding to the power before conversion by the first semiconductor element 21. That is, the first reverse-surface electrode 211 is the drain electrode of the first semiconductor element The 21. first reverse-surface electrode 211 is electrically bonded to the first obverse surface 121A via a conductive bonding layer 29. Hence, the first reverse-surface electrodes 211 of the first semiconductor elements 21 are electrically connected to the first member 12A. The conductive bonding layer 29 may be a layer of solder, for example. In another example, the conductive bonding layer 29 may be a layer of sintered metal, including silver.

As shown in FIG. 10, the first obverse-surface electrode 212 is disposed opposite to the first reverse-surface electrode 211 in the thickness direction z. The first obverse-surface electrode 212 will carry the current corresponding to the power after conversion by the first semiconductor element 21. That is, the first obverse-surface electrode 212 is the source electrode of the first semiconductor element 21.

As shown in FIG. 10, the first gate electrode 213 is disposed on the same side as the first obverse-surface electrode 212 in the thickness direction z. The first gate electrode 213 receives a gate voltage applied for driving the first semiconductor element 21. As shown in FIG. 3, the first gate electrode 213 is smaller in area than the first obverse-surface electrode 212 as viewed in the thickness direction z.

As shown in FIGS. 6, 7, and 9, the second semiconductor elements 22 are bonded to the second obverse surface 121B of the second member 12B. The second semiconductor elements 22 are identical to the first semiconductor elements 21. Hence, the second semiconductor elements 22 are n-channel, vertical MOSFETs. The second semiconductor elements 22 are aligned in the second direction y.

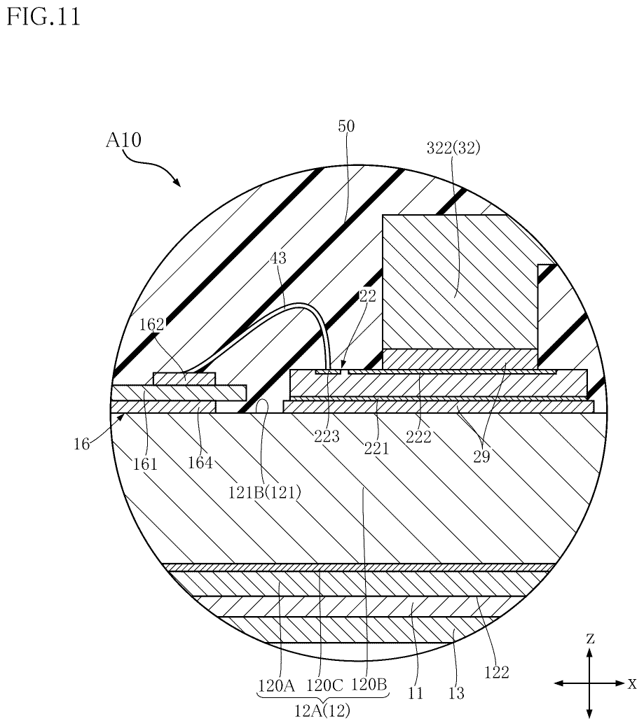

As shown in FIG. 11, each of the second semiconductor elements 22 includes a second reverse-surface electrode 221, a second obverse-surface electrode 222, and a second gate electrode 223.

As shown in FIG. 11, the second reverse-surface electrode 221 faces the second obverse surface 121B of the second member 12B. The second reverse-surface electrode 221 will carry the current corresponding to the power before conversion by the second semiconductor element 22. That is, the second reverse-surface electrode 221 is the drain electrode of the second semiconductor element 22. The second reverse-surface electrode 221 is electrically bonded to the second obverse surface 121B via a conductive bonding layer 29. Hence, the second reverse-surface electrodes 221 of the second semiconductor elements 22 are electrically connected to the second member 12B.

As shown in FIG. 11, the second obverse-surface electrode 222 is disposed opposite to the second reverse-surface electrode 221 in the thickness direction z. The second obverse-surface electrode 222 will carry the current corresponding to the power after conversion by the second semiconductor element 22. That is, the second obverse-surface electrode 222 is the source electrode of the second semiconductor element 22.

As shown in FIG. 11, the second gate electrode 223 is disposed on the same side as the second obverse-surface electrode 222 in the thickness direction z. The second gate electrode 223 receives a gate voltage applied for driving the second semiconductor element 22. As shown in FIG. 4, the second gate electrode 223 is smaller in area than the second obverse-surface electrode 222 as viewed in the thickness direction z.

As shown in FIG. 3, the first wiring 15 is located next to the first semiconductor elements 21 in the first direction x. The first wiring 15 is bonded to the first obverse surface 121A of the first member 12A. For the semiconductor device A10, the first wiring 15 is fabricated from a DBC substrate. As shown in FIGS. 6 and 7, the first wiring 15 includes a first insulating layer 151, a first gate wiring 152, a first sensing wiring 153, and a first support layer 154.

As shown in FIG. 3, the first insulating layer 151 extends in the second direction y. As shown in FIGS. 6 and 7, the first insulating layer 151 is disposed above the first obverse surface 121A of the first member 12A. The first insulating layer 151 is made of a ceramic material containing aluminum nitride, for example.

As shown in FIGS. 3, 6, and 7, the first gate wiring 152 is disposed on the first insulating layer 151. The first gate wiring 152 is disposed on the side opposite to the first member 12A in the thickness direction z with respect to the first insulating layer 151. The first gate wiring 152 extends in the second direction y. The first gate wiring 152 is electrically connected to the first gate electrodes 213 of the first semiconductor elements 21. The first gate wiring 152 includes copper in its composition.

As shown in FIGS. 3, 6, and 7, the first sensing wiring 153 is disposed on the first insulating layer 151. In the first direction x, the first sensing wiring 153 is disposed on the side opposite to the first semiconductor elements 21 with respect to the first gate wiring 152. In the thickness direction z, the first sensing wiring 153 is disposed on the same side as the first gate wiring 152 with respect to the first insulating layer 151. The first sensing wiring 153 extends in the second direction y. The first sensing wiring 153 is electrically connected to the first obverse-surface electrodes 212 of the first semiconductor elements 21. The first sensing wiring 153 includes copper in its composition.

As shown in FIGS. 6, 7, and 10, the first support layer 154 is disposed on the side opposite to the first gate wiring 152 and the first sensing wiring 153 in the thickness direction z with respect to the first insulating layer 151. The first support layer 154 is bonded to the first obverse surface 121A of the first member 12A via, for example, a brazing filler material. The first support layer 154 includes copper in its composition.

As shown in FIG. 3, each first wire 41 is electrically bonded to the first gate electrode 213 of one of the first semiconductor elements 21 and the first gate wiring 152 of the first wiring 15. This electrically connects the first gate electrodes 213 of the first semiconductor elements 21 to the first gate wiring 152. The first wires 41 include gold (Au) in their composition. In other examples, the first wires 41 may include copper or aluminum (Al) in their composition.

As shown in FIG. 3, each second wire 42 is electrically bonded to the first obverse-surface electrode 212 of one of the first semiconductor elements 21 and the first sensing wiring 153 of the first wiring 15. This electrically connects the first obverse-surface electrodes of 212 the first semiconductor elements 21 to the first sensing wiring 153. The second wires 42 include gold in their composition. In other examples, the second wires 42 may include copper or aluminum in their composition.

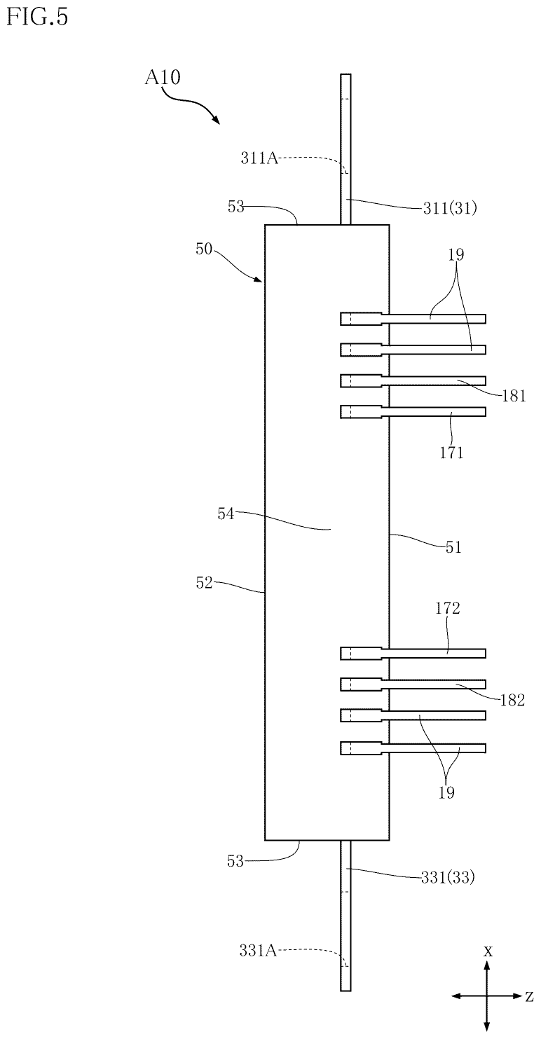

As shown in FIGS. 2 and 3, the first gate terminal 171 is located next to the first member 12A in the second direction y. The first gate terminal 171 is electrically connected to the first gate wiring 152 of the first wiring 15. The first gate terminal 171 is a metal lead made of a material containing copper or a copper alloy. As shown in FIG. 4, a portion of the first gate terminal 171 is covered with the sealing resin 50. The first gate terminal 171 has an L shape as viewed in the first direction x. As shown in FIGS. 5 and 8, the first gate terminal 171 has a portion standing in the thickness direction z. The standing portion is exposed to the outside from the sealing resin 50. The first gate terminal 171 receives a gate voltage applied for driving the first semiconductor elements 21.

As shown in FIGS. 2 and 3, the first sensing terminal 181 is located next to the first gate terminal 171 in the first direction x. The first sensing t terminal 181 is electrically connected to the first sensing wiring 153 of the first wiring 15. The first sensing terminal 181 is a metal lead made of a material containing copper or a copper alloy. As shown in FIG. 4, a portion of the first sensing terminal 181 is covered with the sealing resin 50. The first sensing terminal 181 has an L shape as viewed in the first direction x. As shown in FIG. 5, the first sensing terminal 181 has a portion standing in the thickness direction z. The standing portion is exposed to the outside from the sealing resin 50. The first sensing terminal 181 receives a voltage of the same potential as the voltage applied to the first obverse-surface electrodes 212 of the first semiconductor elements 21.

As shown in FIG. 3, the second wiring 16 is located next to the second semiconductor elements 22 in the first direction X. The second wiring 16 is bonded to the second obverse surface 121B of the second member 12B. For the semiconductor device A10, the second wiring 16 is fabricated from a DBC substrate as with the first wiring 15. As shown in FIGS. 6 and 7, the second wiring 16 includes a second insulating layer 161, a second gate wiring 162, a second sensing wiring 163, and a second support layer 164.

As shown in FIG. 3, the second insulating layer 161 extends in the second direction y. As shown in FIGS. 6 and 7, the second insulating layer 161 is disposed above the second obverse surface 121B of the second member 12B. The second insulating layer 161 is made of a ceramic material containing aluminum nitride, for example.

As shown in FIGS. 3, 6, and 7, the second gate wiring 162 is disposed on the second insulating layer 161. The second gate wiring 162 is disposed on the side opposite to the second member 12B in the thickness direction z with respect to the second insulating layer 161. The second gate wiring 162 extends in the second direction y. The second gate wiring 162 is electrically connected to the second gate electrodes 223 of the second semiconductor elements 22. The second gate wiring 162 includes copper in its composition.

As shown in FIGS. 3, 6, and 7, the second sensing wiring 163 is disposed on the second insulating layer 161. In the first direction x, the second sensing wiring 163 is disposed on the side opposite to the second semiconductor elements 22 with respect to the second gate wiring 162. In the thickness direction z, the second sensing wiring 163 is disposed on the same side as the second gate wiring 162 with respect to the second insulating layer 161. The second sensing wiring 163 extends in the second direction y. The second sensing wiring 163 is electrically connected to the second obverse-surface electrodes 222 of the second semiconductor elements 22. The second sensing wiring 163 includes copper in its composition.

As shown in FIGS. 6, 7, and 11, the second support layer 164 is disposed on the side opposite to the second gate wiring 162 and the second sensing wiring 163 in the thickness direction z with respect to the second insulating layer 161. The second support layer 164 is bonded to the second obverse surface 121B of the second member 12B via, for example, a brazing filler material. The second support layer 164 includes copper in its composition.

As shown in FIG. 3, each third wire 43 is electrically bonded to the second gate electrode 223 of one of the second semiconductor elements 22 and the second gate wiring 162 of the second wiring 16. This electrically connects the second gate electrodes 223 of the second semiconductor elements 22 to the second gate wiring 162. The third wires 43 include gold in their composition. In other examples, the third wires 43 may include copper or aluminum in their composition.

As shown in FIG. 3, each fourth wire 44 is electrically bonded to the second obverse-surface electrode 222 of one of the second semiconductor elements 22 and the second sensing wiring 163 of the second wiring 16. This electrically connects the second obverse-surface electrodes 222 of the second semiconductor elements 22 to the second sensing wiring 163. The fourth wires 44 include gold in their composition. In other examples, the fourth wires 44 may include copper or aluminum in their composition.

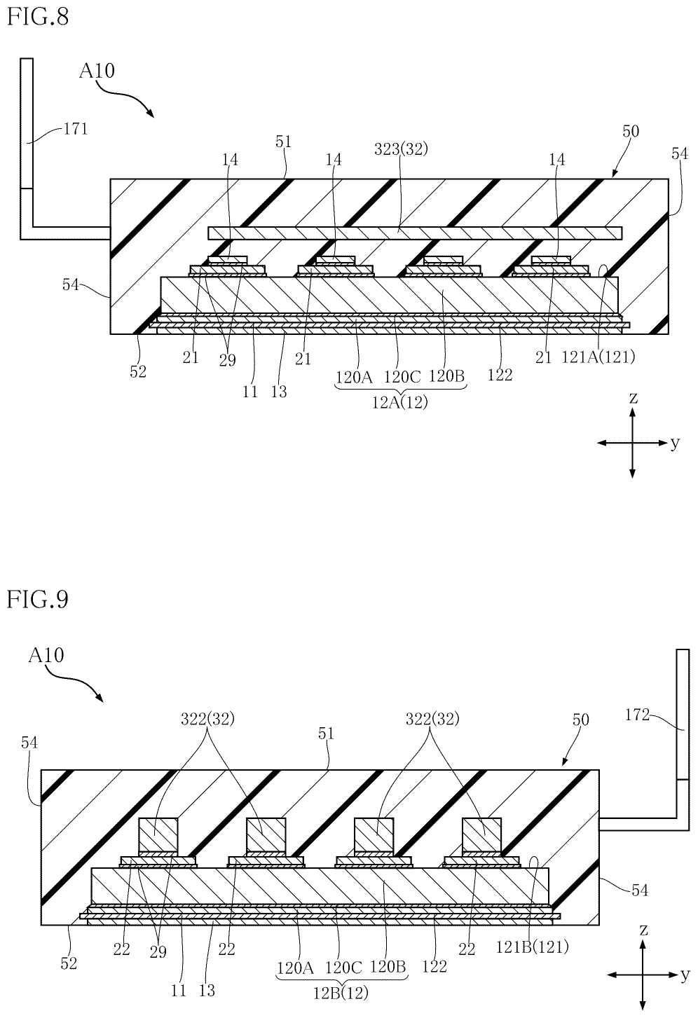

As shown in FIGS. 2 and 3, the second gate terminal 172 is located next to the second member 12B in the second direction y. The second gate terminal 172 is disposed on the same side as the first gate terminal 171 in the second direction y with respect to the insulating members 11. The second gate terminal 172 is electrically connected to the second gate wiring 162 of the second wiring 16. The second gate terminal 172 is a metal lead made of a material containing copper or a copper alloy. As shown in FIG. 4, a portion of the second gate terminal 172 is covered with the sealing resin 50. The second gate terminal 172 has an L shape as viewed in the first direction x. As shown in FIGS. 5 and 9, the second gate terminal 172 has a portion standing in the thickness direction z. The standing portion is exposed to the outside from the sealing resin 50. The second gate terminal 172 receives a gate voltage applied for driving the second semiconductor elements 22.

As shown in FIGS. 2 and 3, the second sensing terminal 182 is located next to the second gate terminal 172 in the first direction x. The second sensing terminal 182 is electrically connected to the second sensing wiring 163 of the second wiring 16. The second sensing terminal 182 is a metal lead made of a material containing copper or a copper alloy. As shown in FIG. 4, a portion of the second sensing terminal 182 is covered with the sealing resin 50. The second sensing terminal 182 has an L shape as viewed in the first direction x. As shown in FIG. 5, the second sensing terminal 182 has a portion standing in the thickness direction z. The standing portion is exposed to the outside from the sealing resin 50. The second sensing terminal 182 receives a voltage of the same potential as the voltage applied to the second obverse-surface electrodes 222 of the second semiconductor elements 22.

As shown in FIG. 3, the fifth wires 45 include one electrically bonded to the first gate terminal 171 and the first gate wiring 152 of the first wiring 15 and one electrically bonded to the first sensing terminal 181 and the first sensing wiring 153 of the first wiring 15. In this way, the first gate terminal 171 is electrically connect to the first gate electrodes 213 of the first semiconductor elements 21 via the first gate wiring 152. The first sensing terminal 181 is electrically connected to the first obverse-surface electrodes 212 of the first semiconductor elements 21 via the first sensing wiring 153.

As shown in FIG. 3, the fifth wires 45 additionally include one electrically bonded to the second gate terminal 172 and the second gate wiring 162 of the second wiring 16 and one electrically bonded to the second sensing terminal 182 and the second sensing wiring 163 of the second wiring 16. In this way, the second gate terminal 172 is electrically connect to the second gate electrodes 223 of the second semiconductor elements 22 via the second gate wirings 162. The second sensing terminal 182 is electrically connected to the second obverse-surface electrodes 222 of the second semiconductor elements 22 via the second sensing wiring 163. The fifth wires 45 include gold in their composition. In other examples, the fifth wires 45 may include copper or aluminum in their composition.

As shown in FIGS. 2 and 3, the semiconductor device A10 additionally includes four dummy terminals 19. Two of the four dummy terminals 19 are disposed opposite to the first gate terminal 171 in the first direction x with respect to the first sensing terminal 181. The other two dummy terminals 19 are disposed opposite to the second gate terminal 172 in the first direction x with respect to the second sensing terminal 182. The dummy terminals 19 are metal leads made of a material containing copper or a copper alloy. The dummy terminals 19 are identical in shape to the first gate terminal 171. A portion of each dummy terminal 19 is covered with the sealing resin. Each dummy terminal 19 has a portion standing in the thickness direction z and exposed to the outside from the sealing resin 50.

As shown in FIGS. 2 and 3, the first terminal 31 is disposed on the side opposite to the second semiconductor elements 22 in the first direction x with respect to the first semiconductor elements 21. As shown in FIG. 6, the first terminal 31 includes a first terminal portion 311 and a first support base 312. The first terminal portion 311 is electrically bonded to the first obverse surface 121A of the first member 12A via the first support base 312. The first terminal portion 311 is thus spaced apart from the first member 12A in the thickness direction z. As shown in FIG. 3, the first terminal portion 311 overlaps with the first member 12A as viewed in the thickness direction z. The first terminal portion 311 includes copper in its composition.

The first terminal 31 is electrically connected to the first member 12A. The first terminal 31 is thus electrically connected to the first reverse-surface electrodes 211 of the first semiconductor elements 21 via the first member 12A. The first terminal portion 311 is a P terminal (positive electrode) to which the DC voltage to be converted is applied.

As shown in FIG. 6, the first terminal portion 311 is partly exposed to the outside from the sealing resin 50. The first terminal portion 311 has a first mounting hole 311A in the portion exposed from the sealing resin 50. The first mounting hole 311A extends through the first terminal portion 311 in the thickness direction z.

As shown in FIGS. 3, 6, and 7, each conducting member 14 is electrically bonded to the first obverse-surface electrode 212 of a first semiconductor element 21 and the second obverse surface 121B of the second member 12B via a conductive bonding layer 29. This electrically connects the second member 12B to the first obverse-surface electrodes 212 of the first semiconductor elements 21. The conducting members 14 extend in the first direction x. The conducting members 14 include copper in their composition. For the semiconductor device A10, the conducting members 14 are metal leads. In another example, the conducting members 14 may be wires.

As shown in FIGS. 2, 6, and 7, the second terminal 32 extends across the gap between the first member 12A and the second member 12B and is spaced apart from the first member 12A and the second member 12B in the thickness direction z. The second terminal 32 includes copper in its composition. The second terminal 32 includes a second terminal portion 321, a plurality of connecting portions 322, a first interconnecting portion 323, and a second interconnecting portion 324.

As shown in FIGS. 6, 7, and 9, each connecting portion 322 is electrically bonded to the second obverse-surface electrode 222 of a second semiconductor element 22 via a conductive bonding layer 29. The connecting portions 322 extend in the first direction x.

As shown in FIGS. 2 and 8, the first interconnecting portion 323 extends in the second direction y. The connecting portions 322 are connected to the first interconnecting portion 323. The second interconnecting portion 324 is located on the side opposite to the connecting portions 322 in the first direction X with respect to the first interconnecting portion 323. The second interconnecting portion 324 is connected to the first interconnecting portion 323. The second interconnecting portion 324 extends in the first direction x. As viewed in the thickness direction z, the first interconnecting portion 323 and the second interconnecting portion 324 overlap with the first member 12A. That is, the second terminal 32 overlaps with the first member 12A as viewed in the thickness direction z.

As shown in FIG. 2, the second terminal portion 321 is located on the side opposite to the second semiconductor elements 22 in the first direction x with respect to the first semiconductor elements 21. The second terminal portion 321 is spaced apart from the first terminal portion 311 in the second direction y. The second terminal portion 321 is spaced apart from the first member 12A in the thickness direction z. The second terminal portion 321 includes copper in its composition.

As shown in FIG. 2, the second terminal portion 321 is connected to the second interconnecting portion 324 of the second terminal 32. Hence, the second terminal 32 is electrically connected to the second obverse-surface electrodes 222 of the second semiconductor elements 22. The second terminal portion 321 is an N terminal (negative electrode) to which the DC voltage to be converted is applied.

As shown in FIG. 7, the second terminal portion 321 is partly exposed to the outside from the sealing resin 50. The second terminal portion 321 has a second mounting hole 321A in the portion exposed from the sealing resin 50. The second mounting hole 321A extends through the second terminal portion 321 in the thickness direction z.

As shown in FIGS. 2 and 3, the third terminal 33 is disposed on the side opposite to the first terminal 31 and the second terminal portion 321 of the second terminal 32 in the first direction x with respect to the first semiconductor elements 21. As shown in FIG. 6, the third terminal 33 includes a third terminal portion 331 and a second support base 332. The third terminal portion 331 is electrically bonded to the second obverse surface 121B of the second member 12B via the second support base 332. The third terminal portion 331 is thus spaced apart from the second member 12B in the thickness direction z. The third terminal portion 331 includes copper in its composition.

The third terminal 33 is electrically connected to the second member 12B. The third terminal 33 is thus electrically connected to the second reverse-surface electrodes 221 of the second semiconductor elements 22 via the second member 12B. The third terminal portion 331 outputs the AC power converted by the first semiconductor elements 21 and the second semiconductor elements 22.

As shown in FIG. 6, the third terminal portion 331 is partly exposed to the outside from the sealing resin 50. The third terminal portion 331 has a third mounting hole 331A in the portion exposed from the sealing resin 50. The third mounting hole 331A extends through the third terminal portion 331 in the thickness direction z.

As shown in FIGS. 6 to 9, the sealing resin 50 covers the two conductive members 12, the first wiring 15, the second wiring 16, the first semiconductor elements 21, and the second semiconductor elements 22. In addition, the sealing resin 50 partly covers the first terminal 31, the second terminal 32, the third terminal 33, the first gate terminal 171, the second gate terminal 172, the first sensing terminal 181, the second sensing terminal 182, and the dummy terminals 19. The sealing resin 50 is electrically insulating. The sealing resin 50 is made of a material containing a black epoxy resin, for example. As shown in FIG. 5, the sealing resin 50 has a top surface 51, a bottom surface 52, two first side surfaces 53, and two second side surfaces 54.

As shown in FIGS. 6 to 9, the top surface 51 faces the same side as the first obverse surface 121A of the first member 12A in the thickness direction z. The bottom surface 52 faces away from the top surface 51 in the thickness As shown in FIG. 4, a portion of the heat direction z. dissipating layer 13 is exposed at the bottom surface 52.

As shown in FIGS. 6 and 7, the two first side surfaces 53 are spaced apart from each other in the first direction x and connected to the top surface 51 and the bottom surface 52. The first terminal portion 311 of the first terminal 31 and the second terminal portion 321 of the second terminal 32 are partly exposed from one of the two first side surfaces 53. The third terminal portion 331 of the third terminal 33 is partly exposed from the other first side surface 53. As shown in FIGS. 8 and 9, the two second side surfaces 54 are spaced apart from each other in the second direction y and are connected to the top surface 51 and the bottom surface 52. The first gate terminal 171, the second gate terminal 172, the first sensing terminal 181, the second sensing terminal 182, and the dummy terminals 19 are partly exposed from one of the two second side surfaces 54.

### Variation of First Embodiment

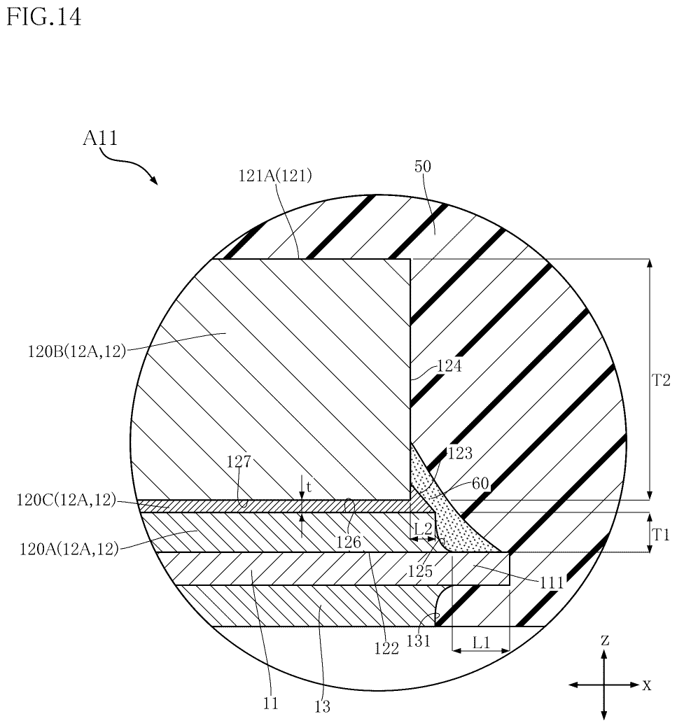

With reference to FIG. 14, the following describes a semiconductor device A11 according to a variation of the semiconductor device A10.

As shown in FIG. 14, for the semiconductor device A11, the first layer 120A of each of the two conductive members 12 has a third end surface 125 that is different in configuration from that of the first layer 120A for the semiconductor device Specifically, the third end surface 125 of the first A10. layer 120A is concave inward.

The following describes the operation and effect of the semiconductor device A10.

The semiconductor device A10 includes a conductive member 12 having an obverse surface 121 and a reverse surface 122 and a sealing resin 50 covering the conductive member 12. As viewed in thickness direction z, the obverse surface 121 is surrounded by the peripheral edge of the reverse surface 122. The conductive member 12 has a first end surface 123 located between the obverse surface 121 and the reverse surface 122 in the thickness direction z. The first end surface 123 is inclined relative to the reverse surface 122. As viewed in the thickness direction z, the first end surface 123 overlaps with the reverse surface 122. Due to this configuration, where the primer 60 is in contact with the first end surface 123 as shown in FIG. 13, the component of the weight of the primer 60 parallel to the inclination of the first end surface 123 decreases, and the friction acting on the primer 60 on the first end surface 123 increases. This can reduce the volume of primer 60 that runs off the conductive member 12 in the process of forming the sealing resin 50. The semiconductor device A10 can therefore suppress the void formation at the interface between the conductive member 12 and the sealing resin 50.

In the semiconductor device A10, the conductive member 12 includes a first layer 120A having the reverse surface 122, a second layer 120B having the obverse surface 121, and a first end surface 123 having the bonding layer 120C. The bonding layer 120C electrically bonds the first layer 120A and the second layer 120B. The bonding layer 120C is in contact with the second end surface 124. With this configuration, the bonding layer 120C is less likely to have a recess that can cause a void to form in the sealing resin 50.

The first layer 120A of the conductive member 12 has a third end surface 125 connected to the reverse surface 122. The third end surface 125 is inclined relative to the reverse surface 122. As viewed in the thickness direction z, the third end surface 125 overlaps with the reverse surface 122. With this configuration, where the primer 60 is in contact with the third end surface 125, the effect similar to that achieved between the first end surface 123 and the primer 60 is achieved between the third end surface 125 and the primer 60. This can further reduce the volume of primer 60 that runs off the conductive member 12 in the process of forming the sealing resin 50.

The semiconductor device A10 additionally includes an insulating member 11 bonded to the reverse surface 122 of the conductive member 12. The insulating member 11 has a peripheral portion 111 that extends outward from the conductive member 12 as viewed in the thickness direction z. The primer 60 is in contact with the peripheral portion 111. Here, the peripheral portion 111 has a greater dimension in the first direction x than the first end surface 123. With this configuration, the primer 60 flowing down along the conductive member 12 is received by the peripheral portion 111. This can efficiently reduce the volume of primer 60 that runs off the conductive member 12.

For the semiconductor device A11, the first layer 120A of the conductive member 12 has a third end surface 125 that is concave inward. With this configuration, the third end surface 125 has a larger area in contact with the primer 60. In addition, an anchoring effect is produced between the primer 60 and the third end surface 125, thereby reducing the volume of the primer 60 that runs off the conductive member 12.

In the conductive member 12, the dimension T2 of the second layer 120B in the thickness direction z is greater than the dimension T1 of the first layer 120A in the thickness direction. The second layer 120B thus transmits a greater amount of heat in a direction orthogonal to the thickness direction z, thereby suppressing an increase in the thermal resistance of the first layer 120A in the thickness direction z.

The semiconductor device A10 additionally includes a heat dissipating member 13 disposed opposite to the conductive member 12 in the thickness direction z with respect to the insulating member 11. The heat dissipating member 13 is bonded to the insulating member 11 and exposed to the outside from the sealing resin 50. This configuration improves the heat dissipation of the semiconductor device A10.

### Second Embodiment

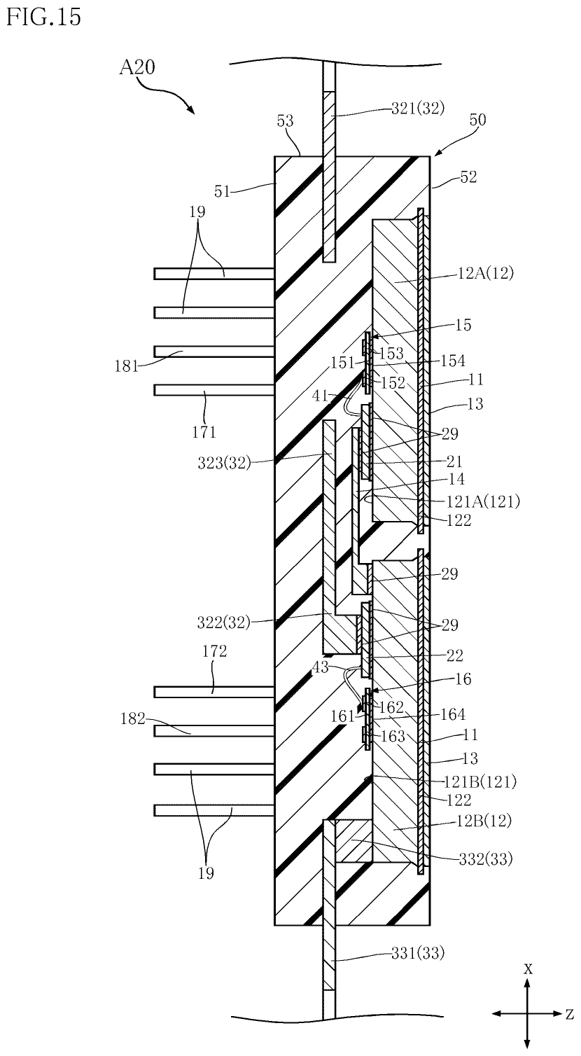

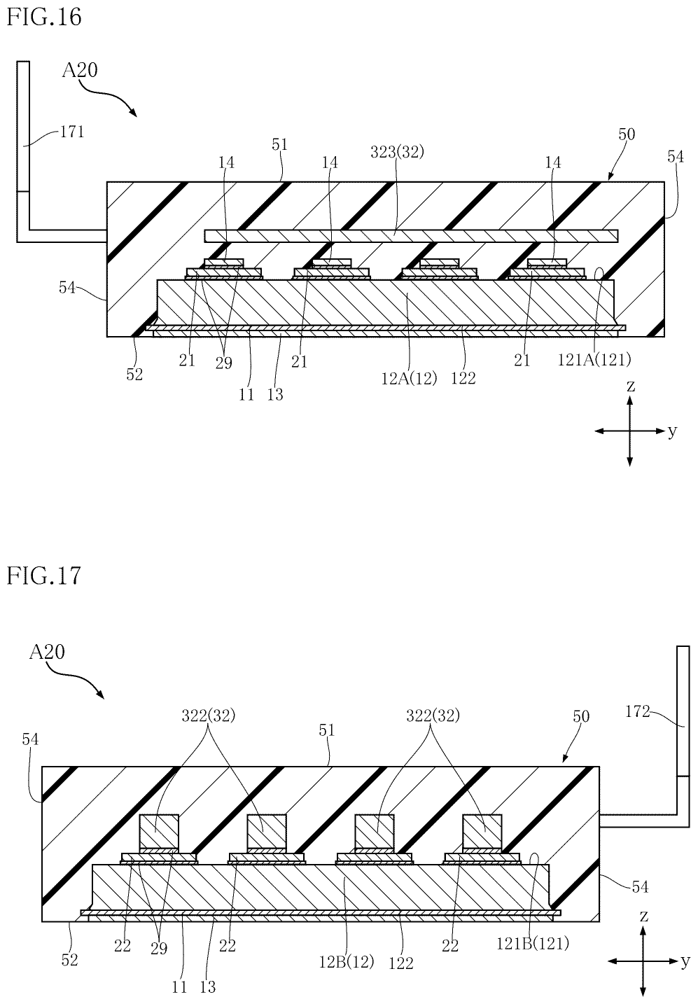

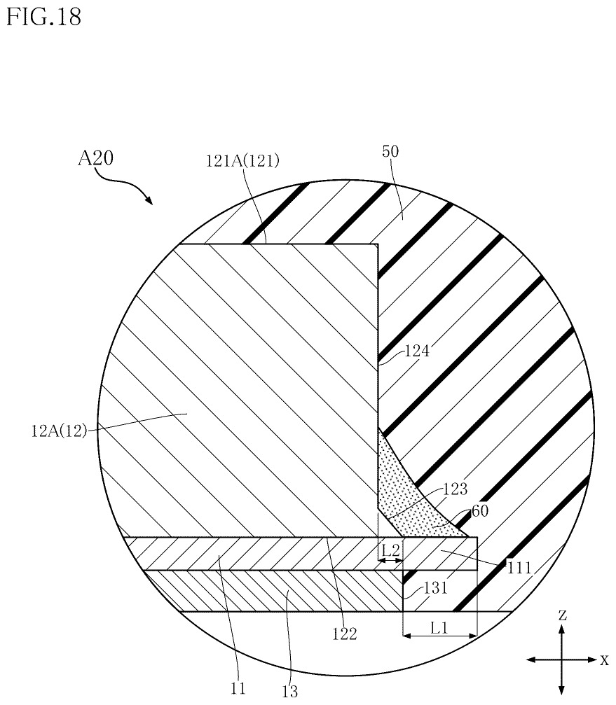

With reference to FIGS. 15 to 18, the following describes a semiconductor device A20 according to a second embodiment of the present disclosure. In these figures, the elements identical or similar to those of the semiconductor device A10 described above are denoted by the same reference numerals, and overlapping descriptions are omitted. Note that the section shown in FIG. 15 corresponds in position to the section of the semiconductor device A10 shown in FIG. 7. Similarly, the section shown in FIG. 16 corresponds in position to the section of the semiconductor device A10 shown in FIG. 8. The section shown in FIG. 17 corresponds in position to the section of the semiconductor device A10 shown in FIG. 9.

For the semiconductor device A20, the two conductive members 12 are different in configuration from those of the semiconductor device A10.

As shown in FIGS. 15 to 17, the two conductive members 12 (the first member 12A and the second member 12B) do not include a first layer 120A, a second layer 120B, and a bonding layer 120C. Each conductive member 12 is composed of a single metal layer. The two conductive members 12 include copper in their composition.

As shown in FIG. 18, each of the two conductive members 12 does not have a first bonding surface 126 and a second bonding surface 127 as there is no bonding layer 120C. Each of the two conductive members 12 has a first end surface 123 connected to the reverse surface 122 and a second end surface 124 connected to the obverse surface 121 and the first end surface 123. That is, each of the two conductive members 12 does not have a third end surface 125. The dimension of the second end surface 124 in the thickness direction z is greater than the dimension of the first end surface 123 in the thickness direction z. The primer 60 is in contact with the first end surface 123, the second end surface 124, and the peripheral portion 111 of the insulating member 11.

The following describes the operation and effect of the semiconductor device A20.

The semiconductor device A20 includes a conductive member 12 having an obverse surface 121 and a reverse surface 122 and a sealing resin 50 covering the conductive members 12. As viewed in thickness direction z, the obverse surface 121 is surrounded by the peripheral edge of the reverse surface 122. The conductive member 12 has a first end surface 123 located between the obverse surface 121 and the reverse surface 122 in the thickness direction z. The first end surface 123 is inclined relative to the reverse surface 122. As viewed in the thickness direction z, the first end surface 123 overlaps with the reverse surface 122. The semiconductor device A20 can therefore suppress the void formation at the interface between the conductive member 12 and the sealing resin 50. Additionally, the semiconductor device A20 has a configuration in common with the semiconductor device A10 and thus achieves he same effect as the semiconductor device A10.

For the semiconductor device A20, the first end surface 123 of the conductive member 12 is connected to the reverse surface 122. That is, the conductive member 12 is composed of a single metal layer and without a bonding layer 120C. The conductive member 12 of this configuration is free of junctions such as a first bonding surface 126 and a second bonding surface 127, so that a reduction in the thermal resistance or electrical resistance of the conductive member 12 is suppressed.

The second end surface 124 of the conductive member 12 is greater in dimension in the thickness direction z than the first end surface 123 of the conductive member 12. With this configuration, the conductive member 12 is enabled to transfer a greater amount of heat in a direction orthogonal to the thickness direction z without the need to excessively reduce the area of the obverse surface 121.

### Third Embodiment

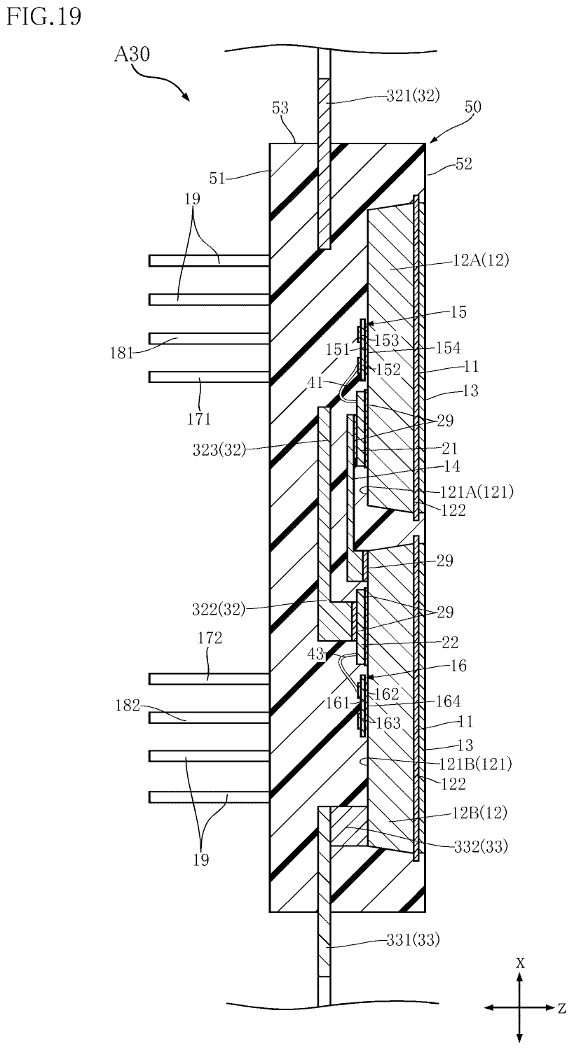

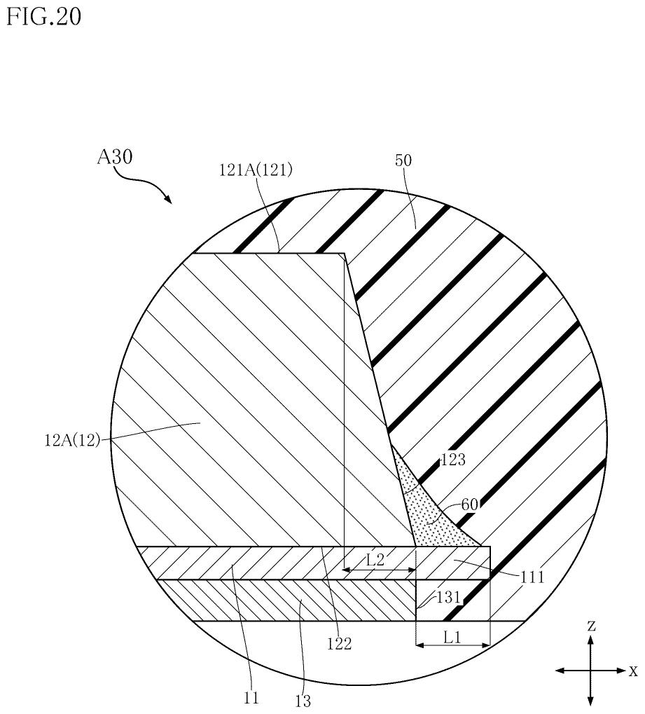

With reference to FIGS. 19 and 20, the following describes a semiconductor device A30 according to a third embodiment of the present disclosure. In these figures, the elements identical or similar to those of the semiconductor device A10 described above are denoted by the same reference numerals, and overlapping descriptions are omitted. Note that the section shown in FIG. 19 corresponds in position to the section of the semiconductor device A10 shown in FIG. 7.

For the semiconductor device A30, the two conductive members 12 are different in configuration from those of the semiconductor device A10.

As shown in FIG. 19, the two conductive members 12 (the first member 12A and the second member 12B) do not include a first layer 120A, a second layer 120B, and a bonding layer 120C. That is, the two conductive members 12 are each composed of a single metal layer. The two conductive members 12 include copper in their composition.

As shown in FIG. 20, each of the two conductive members 12 does not have a first bonding surface 126 and a second bonding surface 127 as there is no bonding layer 120C. Each of the two conductive members 12 has a first end surface 123 connected to the reverse surface 122 and the obverse surface 121. That is, each of the two conductive members 12 does not have a second end surface 124 and a third end surface 125. The primer 60 is in contact with the first end surface 123 and the peripheral portion 111 of the insulating member 11.

The following describes the operation and effect of the semiconductor device A30.

The semiconductor device A30 includes a conductive member 12 having an obverse surface 121 and a reverse surface 122 and a sealing resin 50 covering the conductive members 12. As viewed in thickness direction z, the obverse surface 121 is surrounded by the peripheral edge of the reverse surface 122. The conductive member 12 has a first end surface 123 located between the obverse surface 121 and the reverse surface 122 in the thickness direction z. The first end surface 123 is inclined relative to the reverse surface 122. As viewed in the thickness direction z, the first end surface 123 overlaps with the reverse surface 122. Consequently, the semiconductor device A30 can therefore suppress the void formation at the interface between the conductive member 12 and the sealing resin 50. Additionally, the semiconductor device a configuration in A30 has common with the semiconductor device A10 and thus achieves he same effect as the semiconductor device A10.

For the semiconductor device A30, the first end surface 123 of the conductive member 12 is connected to the obverse surface 121 and the reverse surface 122. Supposing that the conductive member 12 is provided with an imaginary plane extending from the peripheral edge of the obverse surface 121 to the reverse surface 122 at an angle of 45° relative to the thickness direction z, the heat conducted to the conductive member 12 can be distributed uniformly in the region surrounded by the imaginary plane. As deduced from this, the configuration of embodiment the present helps the distribution of the heat conducted to the conductive member 12 through the obverse surface 121 to be advantageously uniform in the thickness direction z and a direction orthogonal to the thickness direction z. This further improves the thermal conductivity of the conductive member 12.

The present disclosure is not limited to the embodiments described above. Various modifications in design may be made freely in the specific structure of each part described in the present disclosure.

The present disclosure includes embodiments described in the following clauses.

### Clause 1

A semiconductor device comprising:
a conductive member including an obverse surface and a reverse surface facing away from each other in a thickness direction;
a semiconductor element bonded to the obverse surface; and
a sealing resin covering the conductive member and the semiconductor element,
wherein the obverse surface is surrounded by a peripheral edge of the reverse surface as viewed in the thickness direction,
the conductive member includes a first end surface located between the obverse surface and the reverse surface in the thickness direction,
the first end surface is inclined relative to the reverse surface, and
the first end surface overlaps with the reverse surface as viewed in the thickness direction.

### Clause 2

The semiconductor device according to Clause 1, wherein the conductive member includes a first layer including the reverse surface, a second layer including the obverse surface, and a bonding layer including the first end surface, and
the bonding layer electrically bonds the first layer and the second layer.

### Clause 3

The semiconductor device according to Clause 2, wherein a distance between the first layer and the second layer in the thickness direction is smaller than a dimension of the first layer in the thickness direction.

### Clause 4

The semiconductor device according to Clause 2 or 3, wherein the second layer includes a second end surface connected to the obverse surface, and
the bonding layer is in contact with the second end surface.

### Clause 5

The semiconductor device according to Clause 4, wherein the first layer includes a third end surface connected to the reverse surface, and
the third end surface is inclined relative to the reverse surface, and
the third end surface overlaps with the reverse surface as viewed in the thickness direction.

### Clause 6

The semiconductor device according to Clause 5, wherein the third end surface is concave inward of the first layer.

### Clause 7

The semiconductor device according to Clause 5 or 6, wherein the first layer includes a bonding surface connected to the third end surface and facing the bonding layer, and the bonding layer is in contact with a boundary between the third end surface and the bonding surface.

### Clause 8

The semiconductor device according to any one of Clauses 4 to 7, further comprising a primer in contact with the first end surface and the second end surface.

### Clause 9

The semiconductor device according to Clause 8, further comprising an insulating member bonded to the reverse surface,
wherein the insulating member includes a peripheral portion extending outward from the conductive member as viewed in the thickness direction, and
the primer is in contact with the peripheral portion.

### Clause 10

The semiconductor device according to Clause 9, wherein a dimension of the peripheral portion in a first direction orthogonal to the thickness direction is greater than a dimension of the first end surface in the first direction.

### Clause 11

The semiconductor device according to Clause 9 or 10, wherein the peripheral portion is sandwiched by the sealing resin in the thickness direction.

### Clause 12

The semiconductor device according to any one of Clauses 9 to 11, wherein a dimension of the insulating member in the thickness direction is smaller than a dimension of the first layer in the thickness direction.

### Clause 13

The semiconductor device according to any one of Clauses 9 to 12, further comprising a heat dissipating member disposed opposite to the conductive member in the thickness direction with respect to the insulating member,
wherein the heat dissipating member is bonded to the insulating member and exposed to outside from the sealing resin.

### Clause 14

The semiconductor device according to any one of Clauses 2 to 13, wherein a dimension of the second layer in the thickness direction is greater than a dimension of the first layer in the thickness direction.

### Clause 15

The semiconductor device according to Clause 1, wherein the first end surface is connected to the reverse surface.

### Clause 16

The semiconductor device according to Clause 15, wherein the conductive member includes a second end surface connected to the obverse surface and the first end surface, and
a dimension of the second end surface in the thickness direction is greater than a dimension of the first end surface in the thickness direction.

### Clause 17

The semiconductor device according to Clause 15, wherein the first end surface is connected to the obverse surface.

### Clause 18

The semiconductor device according to any one of Clauses 1 to 17, wherein the semiconductor element includes a reverse-surface electrode facing the obverse surface and an obverse-surface electrode and a gate electrode disposed on a side opposite to a side facing the obverse surface in the thickness direction, and
the reverse-surface electrode is electrically bonded to the obverse surface.

REFERENCE NUMERALS

| | |
|---|---|
| a10, A20, A30: | Semiconductor device |
| 11: | Insulating member |
| 111: | Peripheral portion |
| 12: | Conductive member |
| 12A: | First member |
| 12B: | Second member |
| 121: | Obverse surface |
| 121A: | First obverse surface |
| 121B: | Second obverse surface |
| 122: | Reverse surface |
| 123: | First end surface |
| 124: | Second end surface |
| 125: | Third end surface |
| 126: | First bonding surface |
| 127: | Second bonding surface |
| 120A: | First layer |
| 120B: | Second layer |
| 120C: | Bonding layer |
| 13: | Heat dissipating member |
| 131: | End surface |
| 14: | Conducting member |
| 15: | First wiring |
| 151: | First insulating layer |
| 152: | First gate wiring |
| 153: | First sensing wiring |
| 154: | First support layer |
| 16: | Second wiring |
| 161: | Second insulating layer |
| 162: | Second gate wiring |
| 163: | Second sensing wiring |
| 164: | Second support layer |
| 171: | First gate terminal |
| 172: | Second gate terminal |
| 181: | First sensing terminal |
| 182: | Second sensing terminal |
| 19: | Dummy terminal |
| 21: | First semiconductor element |
| 211: | First reverse-surface electrode |
| 212: | First obverse-surface electrode |
| 213: | First gate electrode |
| 22: | Second semiconductor element |
| 221: | Second reverse-surface electrode |
| 222: | Second obverse-surface electrode |
| 223: | Second gate electrode |
| 29: | Conductive bonding layer |
| 31: | First terminal |
| 311: | First terminal portion |
| 311A: | First mounting hole |
| 312: | First support base |
| 32: | Second terminal |
| 321: | Second terminal portion |
| 321A: | Second mounting hole |
| 322: | Connecting portion |
| 323: | First interconnecting portion |
| 324: | Second interconnecting portion |
| 33: | Third terminal |
| 331: | Third terminal portion |
| 331A: | Third mounting hole |
| 332: | Second support base |
| 41: | First wire |
| 42: | Second wire |
| 43: | Third wire |
| 44: | Fourth wire |
| 45: | Fifth wire |
| 50: | Sealing resin |
| 51: | Top surface |
| 52: | Bottom surface |
| 53: | First side surface |
| 54: | Second side surface |
| 60: | Primer |
| z: | Thickness direction |
| x: | First direction |
| y: | Second direction |

1. A semiconductor device comprising:
a conductive member including an obverse surface and a reverse surface facing away from each other in a thickness direction;
a semiconductor element bonded to the obverse surface; and
a sealing resin covering the conductive member and the semiconductor element,
wherein the obverse surface is surrounded by a peripheral edge of the reverse surface as viewed in the thickness direction,
the conductive member includes a first end surface located between the obverse surface and the reverse surface in the thickness direction,
the first end surface is inclined relative to the reverse surface, and
the first end surface overlaps with the reverse surface as viewed in the thickness direction.

2. The semiconductor device according to claim 1, wherein the conductive member includes a first layer including the reverse surface, a second layer including the obverse surface, and a bonding layer including the first end surface, and
the bonding layer electrically bonds the first layer and the second layer.

3. The semiconductor device according to claim 2, wherein a distance between the first layer and the second layer in the thickness direction is smaller than a dimension of the first layer in the thickness direction.

4. The semiconductor device according to claim 2, wherein the second layer includes a second end surface connected to the obverse surface, and
the bonding layer is in contact with the second end surface.

5. The semiconductor device according to claim 4, wherein
the first layer includes a third end surface connected to the reverse surface, and
the third end surface is inclined relative to the reverse surface, and
the third end surface overlaps with the reverse surface as viewed in the thickness direction.

6. The semiconductor device according to claim 5, wherein the third end surface is concave inward of the first layer.

7. The semiconductor device according to claim 5, wherein the first layer includes a bonding surface connected to the third end surface and facing the bonding layer, and
the bonding layer is in contact with a boundary between the third end surface and the bonding surface.

8. The semiconductor device according to claim 4, further comprising a primer in contact with the first end surface and the second end surface.

9. The semiconductor device according to claim 8, further comprising an insulating member bonded to the reverse surface,
wherein the insulating member includes a peripheral portion extending outward from the conductive member as viewed in the thickness direction, and
the primer is in contact with the peripheral portion.

10. The semiconductor device according to claim 9, wherein a dimension of the peripheral portion in a first direction orthogonal to the thickness direction is greater than a dimension of the first end surface in the first direction.

11. The semiconductor device according to claim 9, wherein the peripheral portion is sandwiched by the sealing resin in the thickness direction.

12. The semiconductor device according to claim 9, wherein a dimension of the insulating member in the thickness direction is smaller than a dimension of the first layer in the thickness direction.

13. The semiconductor device according to claim 9, further comprising a heat dissipating member disposed opposite to the conductive member in the thickness direction with respect to the insulating member,
wherein the heat dissipating member is bonded to the insulating member and exposed to outside from the sealing resin.

14. The semiconductor device according to claim 2, wherein a dimension of the second layer in the thickness direction is greater than a dimension of the first layer in the thickness direction.

15. The semiconductor device according to claim 1, wherein the first end surface is connected to the reverse surface.

16. The semiconductor device according to claim 15, wherein the conductive member includes a second end surface connected to the obverse surface and the first end surface, and
a dimension of the second end surface in the thickness direction is greater than a dimension of the first end surface in the thickness direction.

17. The semiconductor device according to claim 15, wherein the first end surface is connected to the obverse surface.

18. The semiconductor device according to claim 1, wherein the semiconductor element includes a reverse-surface electrode facing the obverse surface and an obverse-surface electrode and a gate electrode disposed on a side opposite to a side facing the obverse surface in the thickness direction, and
the reverse-surface electrode is electrically bonded to the obverse surface.
